(19) United States
(12) Patent Application Publication
(10) Pub. No.: US 2026/0334143 A1
(43) Pub. Date: Oct. 22, 2026

(54) SEMICONDUCTOR WET BENCH, CONTROLLER, AND CONTROLLING METHOD THEREOF

(71) Applicant: Taiwan Semiconductor Manufacturing Company, Ltd., Hsinchu (TW)

(72) Inventor: Hsiao-Neng LIN, Hsinchu (TW)

(73) Assignee: Taiwan Semiconductor Manufacturing Company, Ltd., Hsinchu (TW)

(21) Appl. No.: 19/183,312

(22) Filed: Apr. 18, 2025

(51) Int. Cl. H10P 72/00; G05B 13/02

(52) U.S. Cl. CPC H10P 72/0602; G05B 13/0265

(57) ABSTRACT

A semiconductor wet bench, a controller and a controlling method thereof are provided. The controlling method includes obtaining a temperature in the semiconductor wet bench; obtaining a pattern density of a wafer; inferring, by a machine learning model, a lifting up speed at least according to the temperature and the pattern density; and controlling a lifter according to the lifting up speed.

### BACKGROUND

The disclosure relates in general to a semiconductor processing tool bench and a controlling method thereof, and more particularly to a semiconductor wet bench and a controlling method thereof.

A semiconductor wet bench, may include a fan filter unit (FFU) and an exhaust system 108 used for drying a group of wafers after processing by the semiconductor wet bench (e.g., after wet cleaning, after wet etching, or the like). The FFU may, for example, be mounted over a position at which a stack of wafers is horizontally held by a lifter of the semiconductor processing tool. However, many factors could affect the drying rate and drying results, and could easily cause some acidic stain defects to be remained.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a semiconductor wet bench according to one embodiment of the present disclosure.

FIG. 2 shows an experimental data graph of the semiconductor wet bench.

FIGS. 3A-3C are diagrams of an example implementation of the semiconductor wet bench.

FIG. 4 shows a block diagram of the semiconductor wet bench according to one embodiment of the present disclosure.

FIG. 5 shows a flowchart of a controlling method of the semiconductor wet bench according to one embodiment of the present disclosure.

FIG. 6 illustrates the step S200 in the FIG. 5.

FIG. 7 shows a block diagram of the semiconductor wet bench according to another embodiment of the present disclosure.

FIG. 8 shows a flowchart of a controlling method of the semiconductor wet bench according to another embodiment of the present disclosure.

FIG. 9 illustrates the step S200’ in the FIG. 8.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

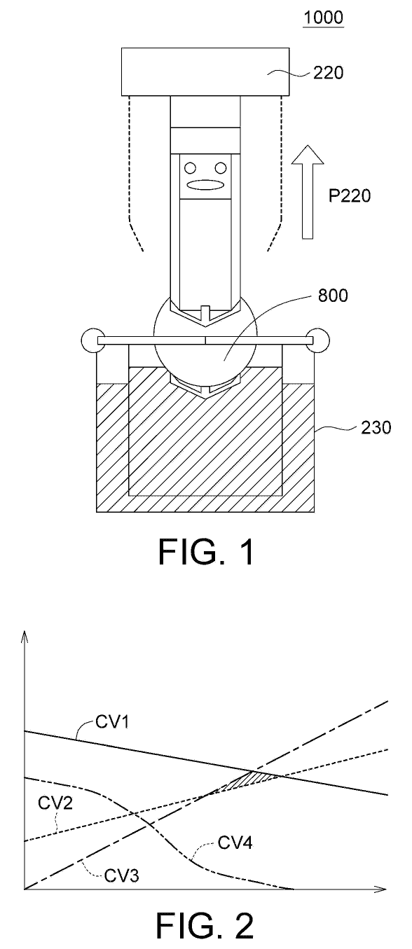

Please refer to FIG. 1, which shows a semiconductor wet bench 1000 according to one embodiment of the present disclosure. A plurality of wafers 800 are carried by a lifter 220 to be immersed into a tank 230. After wet cleaning or wet etching, the wafers are lifted up by the lifter 220. A lifting up speed P220 of the lifter 220 is a key factor to control the amount of acidic stain defects.

Please refer to the FIG. 2, which shows an experimental data graph of the semiconductor wet bench 1000. The curve CV1 shows a humidity change curve, the curve CV2 shows a fan filter unit (FFU) speed change curve, the curve CV3 shows a lifting up speed change curve and the curve CV4 shows a defect count change curve. As shown in the FIG. 2, many factors could affect the drying rate and drying results, and an area A1 is a golden area A1 having minimum amount of the acidic stain defects. The amount of the acidic stain defects is not easily to minimize according to the many factors.

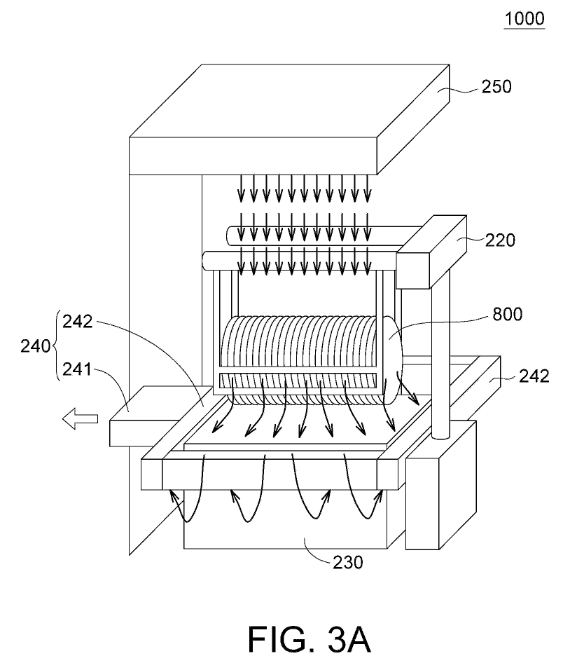

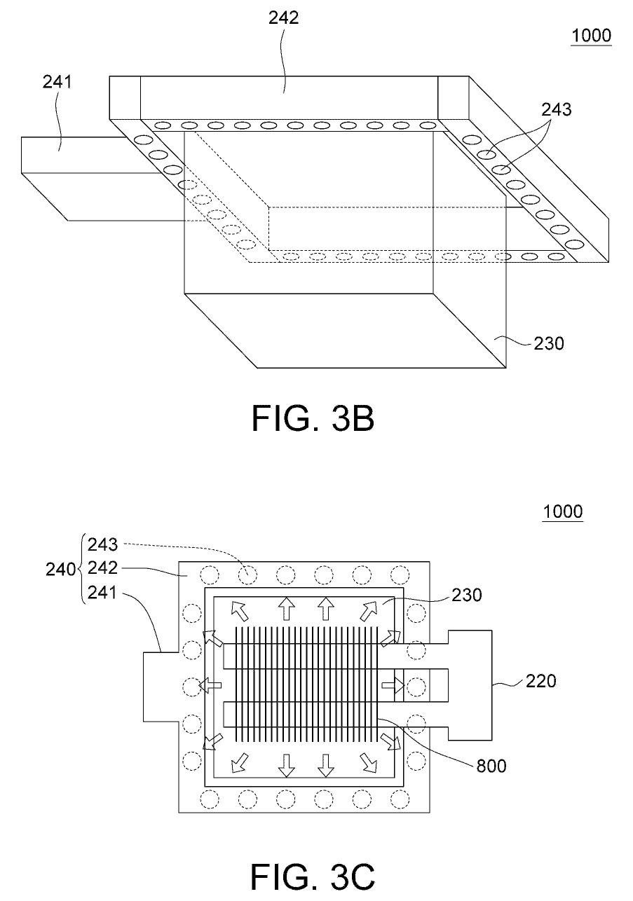

Please refer to FIGS. 3A-3C, which are diagrams of an example implementation of the semiconductor wet bench 1000. The semiconductor wet bench 1000 may be used to perform wet cleaning, wet etching, or another type of semiconductor processing operation.

As shown in the FIGS. 3A-3C, the semiconductor wet bench 1000 includes a tank 230, the lifter 220, a fan filter unit (FFU) 250 and an exhaust system 240, where the exhaust system 240 includes at least one exhaust output 241 and one or more exhaust pipe segments 242. As described in further detail below, the one or more exhaust pipe segments 242 include a plurality of openings 243. FIG. 3A illustrates an isometric view of the semiconductor wet bench 1000 from above the exhaust system 240, FIG. 3B illustrates an isometric view of the tank 230 and the exhaust system 240 from below the exhaust system 240, and the FIG. 3C is a two-dimensional (2D) top view of the semiconductor wet bench 1000 from above the lifter 220.

The tank 230 is a component associated with performing a semiconductor processing operation on one or more wafers 800 (e.g., one or more semiconductor wafers). For example, the tank 230 may be a tank that stores a solution (e.g., a liquid solution) associated with wet cleaning the one or more wafers 800, wet etching the one or more wafers 800, or the like. In some implementations, the one or more wafers 800 may be held above the tank 230 while the FFU 250 provides an airflow toward the one or more wafers 800 (e.g., in association with drying the one or more wafers 800).

The lifter 220 is a component to move, hold, or otherwise control a position of one or more wafers 800 in association with the semiconductor process operation performed by the semiconductor wet bench 1000. For example, the lifter 250 may be capable of grabbing a plurality of wafers 800 (e.g., a stack of wafers in a wafer carrier), submerging the plurality of wafers 800 into a solution in the tank 230, removing the plurality of wafers 800 from the solution, and holding the plurality of wafers 800 over the processing tank 230 (e.g., during drying of the plurality of wafers 800). In some implementations, as indicated in FIG. 3A, the lifter 220 may be arranged to permit the lifter 220 to hold the plurality of wafers 800 such that wafers 800 in the plurality of wafers 800 are horizontally stacked over the tank 230 (e.g., such that top and bottom surfaces of each of the plurality of wafers 800 are oriented in a vertical direction).

The FFU 250 is a component to provide an airflow across surfaces of the plurality of wafers 800 (e.g., in association with drying the wafers 800). For example, the FFU 250 may provide an airflow across (e.g., parallel to) top and bottom surfaces of wafers 800 of the plurality of wafers 800 while the lifter 220 holds the plurality of wafers 800 over the tank 230 after the lifter 220 has removed the plurality of wafers 800 from the tank 230. In some implementations, as shown in the FIG. 3A, the FFU 250 is arranged over the lifter 220 to permit the airflow to be provided across the surfaces of the plurality of wafers 800 in a vertical direction (e.g., a downward direction from the FFU 250 toward the tank 230).

The exhaust system 240 is a component to draw exhaust air from the environment of the semiconductor wet bench 1000 and direct the exhaust air away from the semiconductor wet bench 1000. In some implementations, the exhaust system 240 may draw the exhaust air away from the environment of the semiconductor wet bench 1000 concurrently with the FFU 250 providing the airflow over the surfaces of the plurality of wafers 800 (e.g., such that air flows over the surfaces of the plurality of wafers 800 and is drawn away by the exhaust system 240). As shown, the exhaust system 240 may include at least one exhaust output 241 and one or more exhaust pipe segments 242.

The exhaust output 241 is a component to receive exhaust air from one or more exhaust pipe segments 242 and direct the exhaust air away from the environment of the semiconductor wet bench 1000. In some implementations, as illustrated in the FIGS. 3A-3C, the exhaust system 240 may include a single exhaust output 241, and each of one or more exhaust pipe segments 242 of the exhaust system 240 are connected to the single exhaust output 241. Alternatively, in some implementations, the exhaust system 240 may include a plurality of exhaust outputs 241, and at least one exhaust pipe segment 242 of the one or more exhaust pipe segments 242 is connected to each exhaust output 241 of the plurality of exhaust outputs 241. For example, when the one or more exhaust pipe segments 242 include a first exhaust pipe segment and a second exhaust pipe segment that are not connected to one another, the first exhaust pipe segment may be connected to a first exhaust output on a first side of the tank 230 and the second exhaust pipe segment may be connected to a second exhaust output on a second (e.g., different, such as opposite) side of the tank 230.

The exhaust pipe segment 242 is a component to receive the exhaust air from the environment of the semiconductor wet bench 1000 and provide the exhaust air to an exhaust output 241 (e.g., such that the exhaust air can be directed away from the environment of the semiconductor wet bench 1000 by the exhaust output 241).

In some implementations, the one or more exhaust pipe segments 242 of the exhaust system 240 are arranged substantially around (e.g., on at least two sides of) the tank 230. For example, the one or more exhaust pipe segments 242 may be arranged 360 degrees around the tank 230. In the particular example shown in the FIGS. 3A-3C, the one or more exhaust pipe segments 242 are arranged around an entirety of the perimeter of the tank 230.

In some implementations, the one or more exhaust pipe segments 242 include a plurality of openings 243 to receive exhaust air to be provided to the at least one exhaust output 241. In some implementations, the plurality of openings 243 may be arranged substantially around the perimeter of the tank 230. For example, the plurality of openings 243 may be (evenly) distributed around the perimeter of the tank 230, as shown in the FIGS. 3B and 3C. In some implementations, the plurality of openings 243 are symmetrically arranged with respect to a center axis on a plane corresponding to the tank 230. In some implementations, such an arrangement of the openings 243 causes airflow within the environment of the semiconductor processing tool to be relatively uniformly distributed because exhaust air is drawn into the openings 243 at multiple locations substantially around the perimeter of the tank 230 (e.g., rather than at single location as with prior exhaust outputs). As a result, air flows in all directions around wafers 800 being dried in the wet bench 1000, which results in a more even concentration of acid gas and/or a moisture concentration among the wafers 800, thereby decreasing a defect rate in wafers processed by the semiconductor wet bench 1000.

In some implementations, one or more openings 243 may be on a bottom surface of an exhaust pipe segment 242. That is, in some implementations, one or more openings 243 may be on a surface of the exhaust pipe segment 242 that faces a bottom of the tank 230, or on a surface of the exhaust pipe segment 242 that faces away from the FFU 250. In some implementations, an opening 243 being on the bottom surface of the exhaust pipe segment 242 may act to prevent material (e.g., liquid droplets) from entering the opening 243 that could damage the exhaust pipe segment 242. In some implementations, one or more openings 243 may be on a side surface of an exhaust pipe segment 242 of the one or more exhaust pipe segments 242 (e.g., a surface facing a side of the tank 230, a surface opposite to the surface facing the side of the tank 230, or the like). In some implementations, one or more openings 243 may be on a top surface of an exhaust pipe segment 242 of the one or more exhaust pipe segments 242 (e.g., a surface facing toward the FFU 250). In some implementations, an exhaust pipe segment 242 may include one or more openings 243 on a bottom surface of the exhaust pipe segment 242, one or more openings 243 on a side surface of the exhaust pipe segment 242, and/or one or more openings 243 on a top surface of the exhaust pipe segment 242.

As indicated above, the FIGS. 3A-3C are provided as an example. Other examples may differ from what is described with regard to the FIGS. 3A-3C. The number and arrangement of components shown in the FIGS. 3A-3C are provided as an example. In practice, there may be additional components, fewer components, different components, or differently arranged components than those shown in the FIGS. 3A-3C. Furthermore, two or more components shown in the FIGS. 3A-3C may be implemented within a single component, or a single component shown in the FIGS. 3A-3C may be implemented as multiple, distributed components.

Additionally, or alternatively, a set of components (e.g., one or more components) shown in the FIGS. 3A-3C may perform one or more functions described as being performed by another set of components shown in the FIGS. 3A-3C.

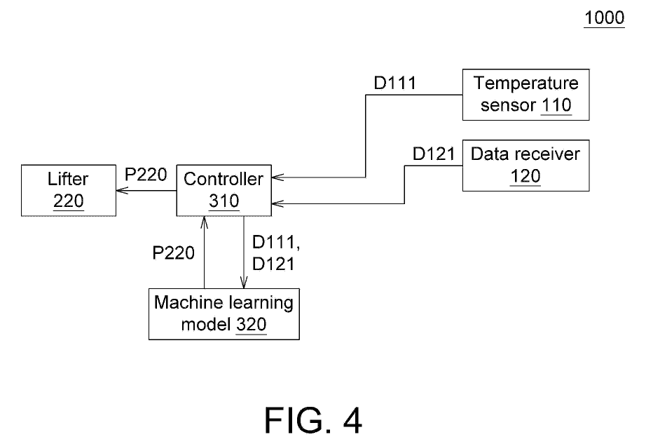

Please refer to FIG. 4, which shows a block diagram of the semiconductor wet bench 1000 according to one embodiment of the present disclosure. The semiconductor wet bench 1000 includes, for example, a temperature sensor 110, a data receiver 120, the lifter 220, a controller 310 and a machine learning model 320. The temperature sensor 110 is connected to the controller 310 and used to detect a temperature D111 in the semiconductor wet bench 1000. The data receiver 120 is connected to the controller 310, and used to receive various data, such as a pattern density D121 of the wafer 800. The controller 310 is connected to the lifter 220 and used to control the lifter 220. The machine learning model 320 is connected to the controller 310 and used to infer the controlling parameter of the lifter 220. The machine learning model 320 could be realized as, for example, a circuit, a circuit board, a storage device storing program codes or a chip. The chip is, for example, a central processing unit (CPU), a programmable general-purpose or special-purpose micro control unit (MCU), a microprocessor, a digital signal processor (DSP), a programmable controller, an application specific integrated circuit (ASIC), a graphics processing unit (GPU), an image signal processor (ISP), an image processing unit (IPU), an arithmetic logic unit (ALU), a complex programmable logic device (CPLD), an embedded system, a field programmable gate array (FPGA), other similar element or a combination thereof. The data receiver 120 is a storage device, a wireless communication module or a wired transmission device.

In one embodiment, the parameter of the lifter 220 is inferred via machine learning technology and big data technology to minimize the acidic stain defects remained on the wafer 800. For example, as shown in the FIG. 4, the lifting up speed P220 is inferred, by the machine learning model 320, according to the temperature D111 and the pattern density D121. The operation of the above components will be explained in detail through the flow chart.

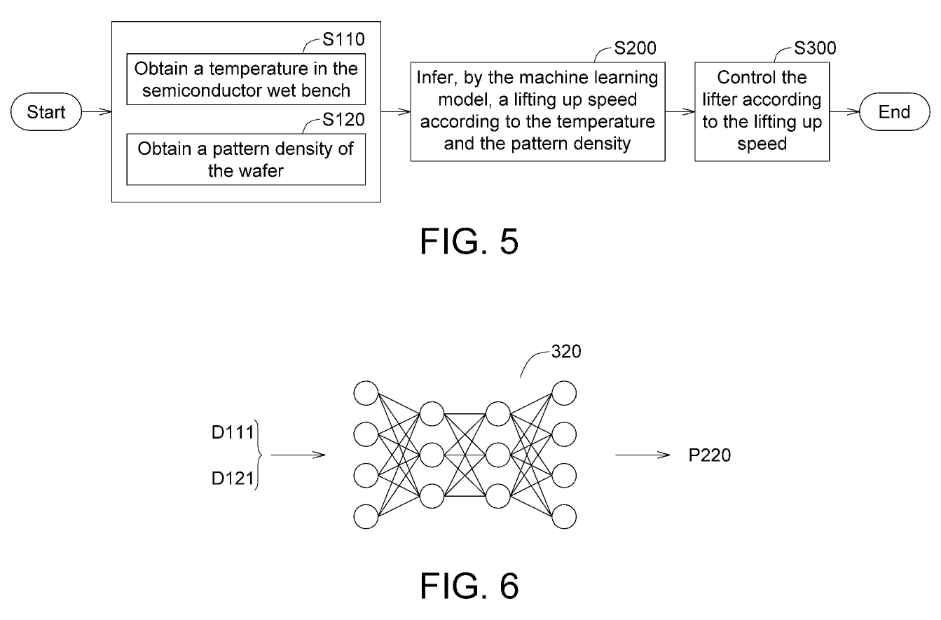

Please refer to FIG. 5, which shows a flowchart of a controlling method of the semiconductor wet bench 1000 according to one embodiment of the present disclosure. The controlling method of the semiconductor wet bench 1000 includes, for example, steps S110, S120, S200 and S300.

In the step S110, the temperature sensor 110 obtains the temperature D111 in the semiconductor wet bench 1000. The temperature D111 is the temperature of the environment in the semiconductor wet bench 1000 and is detected in real time.

In the step S120, the data receiver 120 obtains the pattern density D121 of the wafer 800. The pattern density D121 is, for example, stored in a storage device or inputted by the operator. The step S110 and the S120 could be executed at the same time.

Next, please refer to FIG. 6, which illustrates the step S200 in the FIG. 5. In the step S200, the lifting up speed P220 is inferred, by the machine learning model 320, according to the temperature D111 and the pattern density D121.

Then, in the step S300, the controller 310 controls the lifter 220 according to the lifting up speed P220.

Due to the recipe for the semiconductor wet bench 1000 could be affected by many factors. It is difficult to set the best recipe for the semiconductor wet bench 1000. Based on the AI technology, an optimal recipe could be generated based on various factors.

Further, when the temperature D11 is changed due to the weather or the pattern density D121 is changed due to different lot, the optimal recipe for the semiconductor wet bench 1000 could be obtained immediately. Therefore, the parameter of the semiconductor wet bench 1000 could be adaptively controlled in real time.

Moreover, the amount of the acidic stain defects on the wafer 800 is easily minimized, so the product yield could be improved.

Moreover, any new factors could be added for inferring the parameter of the semiconductor wet bench 1000.

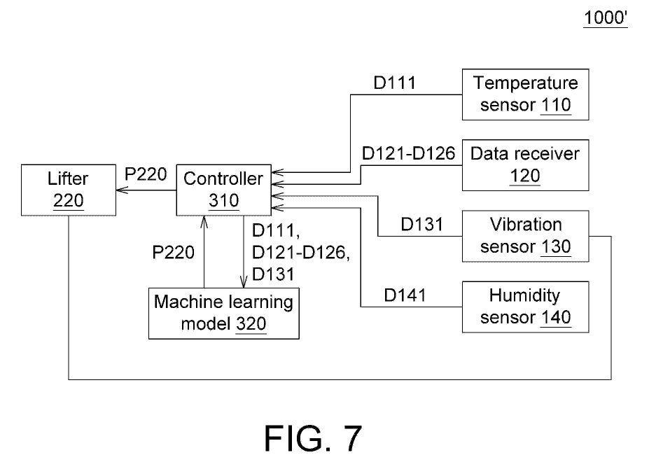

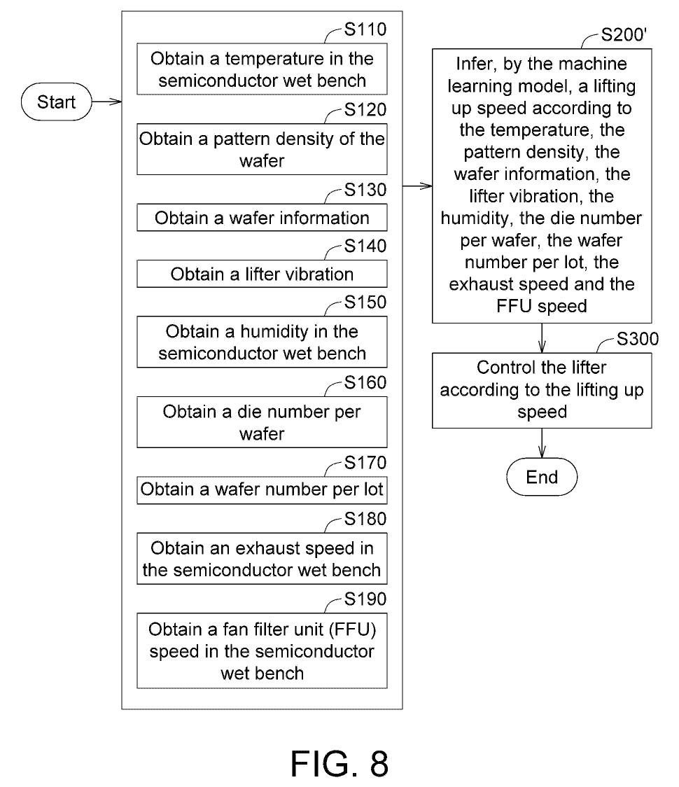

Please refer to FIGS. 7 and 8. FIG. 7 shows a block diagram of the semiconductor wet bench 1000’ according to another embodiment of the present disclosure. FIG. 8 shows a flowchart of a controlling method of the semiconductor wet bench 1000’ according to another embodiment of the present disclosure. In this embodiment, the semiconductor wet bench 1000’ includes, for example, the temperature sensor 110, the data receiver 120, the lifter 220, a vibration sensor 130, a humidity sensor 140, the controller 310 and the machine learning model 320. The data receiver 120 is further used to receive a wafer information D122, a die number per wafer D123, a wafer number per lot D124, an exhaust speed D125 of the exhaust system 240 (shown in the FIGS. 3A-3C), a fan filter unit (FFU) speed D126 of the FFU 250 (shown in the FIGS. 3A-3C). The wafer information D122 includes, for example, a material of a top layer and a material of a substrate of the wafer 800. The vibration sensor 130 is connected to the lifter 220 and the controller 310 and used to obtain a lifter vibration D131. The humidity sensor 140 is connected to the controller 310 and used to obtain a humidity D141 in the semiconductor wet bench 1000. The controlling method of the semiconductor wet bench 1000’ includes, for example, steps S110 to S190, S200’ and S300.

In the step S110, the temperature sensor 110 obtains the temperature D111 in the semiconductor wet bench 1000’. The temperature D111 is the temperature of the environment in the semiconductor wet bench 1000’ and is detected in real time.

In the step S120, the data receiver 120 obtains the pattern density D121 of the wafer 800. The pattern density D121 is, for example, stored in a storage device or inputted by the operator. The step S110 and the S120 could be executed at the same time.

In the step S130, the data receiver 120 obtains the wafer information D122 including the material of the top layer and the material of the substrate of the wafer 800. The wafer information D122 is, for example, stored in a storage device or inputted by the operator.

In the step S140, the vibration sensor 130 obtains the lifter vibration D131. The lifter vibration D131 is the vibration of the lifter 220.

In the step S150, the humidity sensor 140 obtains the humidity D141 in the semiconductor wet bench 1000’. The humidity D141 is the temperature of the environment in the semiconductor wet bench 1000’ and is detected in real time.

In the step S160, the data receiver 120 obtains the die number per wafer D123. The die number per wafer D123 is, for example, stored in a storage device or inputted by the operator.

In the step S170, the data receiver 120 obtains the wafer number per lot D124. The wafer number per lot D124 is, for example, stored in a storage device, or inputted by the operator.

In the step S180, the data receiver 120 obtains the exhaust speed D125 in the semiconductor wet bench 1000’. The exhaust speed D125 is, for example, stored in a storage device, or inputted by the operator, or obtained from the exhaust system 240.

In the step S190, the data receiver 120 obtains the FFU speed D126. The FFU speed D126 is, for example, stored in a storage device, or inputted by the operator, or obtained from the FFU 250. The steps S110 to S190 are, for example, executed at the same time.

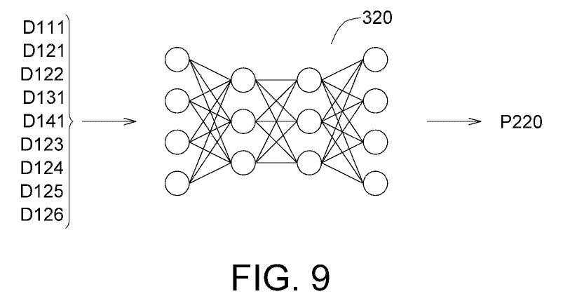

Next, please refer to FIG. 9, which illustrates the step S200’ in the FIG. 8. In the step S200’, the lifting up speed P220 is inferred, by the machine learning model 320, according to the temperature D111, the pattern density D121, the wafer information D122, the lifter vibration D131, the humidity D141, the die number per wafer D123, the wafer number per lot D124, the exhaust speed D125 and the FFU speed D126.

Then, in the step S300, the controller 310 controls the lifter 220 according to the lifting up speed P220.

Due to the recipe for the semiconductor wet bench 1000’ could be affected by many factors. It is difficult to set the best recipe for the semiconductor wet bench 1000’. Based on the AI technology, an optimal recipe could be generated based on various factors.

Further, when the temperature D11 is changed due to the weather or the pattern density D121 is changed due to different lot, the optimal recipe for the semiconductor wet bench 1000’ could be obtained immediately. Therefore, the parameter of the semiconductor wet bench 1000’ could be adaptively controlled in real time.

Moreover, the amount of the acidic stain defects on the wafer 800 is easily minimized, so the product yield could be improved.

Moreover, any new factors could be added for inferring the parameter of the semiconductor wet bench 1000’.

This disclosure uses the above embodiments as examples for explanation. In other embodiment, any one or more of the steps S110 to S190 could be adopted in the controlling method. The present disclosure is not limited to the above embodiments.

According to one example embodiment, a controlling method of a semiconductor wet bench is provided. The controlling method includes obtaining a temperature in the semiconductor wet bench; obtaining a pattern density of a wafer; inferring, by a machine learning model, a lifting up speed at least according to the temperature and the pattern density; and controlling a lifter according to the lifting up speed.

According to one example embodiment, the controlling method described in the previous embodiments further includes: obtaining a wafer information including a material of a top layer and a material of a substrate of the wafer. The lifting up speed is inferred by the machine learning model according to the temperature, the pattern density and the wafer information.

According to one example embodiment, the controlling method described in the previous embodiments further includes: obtaining a lifter vibration. The lifting up speed is inferred by the machine learning model according to the temperature, the pattern density and the lifter vibration.

According to one example embodiment, the controlling method described in the previous embodiments further includes: obtaining a humidity in the semiconductor wet bench. The lifting up speed is inferred by the machine learning model according to the temperature, the pattern density and the humidity.

According to one example embodiment, the controlling method described in the previous embodiments further includes: obtaining a die number per wafer. The lifting up speed is inferred by the machine learning model according to the temperature, the pattern density and the die number per wafer.

According to one example embodiment, the controlling method described in the previous embodiments further includes: obtaining a wafer number per lot. The lifting up speed is inferred by the machine learning model according to the temperature, the pattern density and the wafer number per lot.

According to one example embodiment, the controlling method described in the previous embodiments further includes: obtaining an exhaust speed in the semiconductor wet bench. The lifting up speed is inferred by the machine learning model according to the temperature, the pattern density and the exhaust speed.

According to one example embodiment, the controlling method described in the previous embodiments further includes: obtaining a fan filter unit (FFU) speed in the semiconductor wet bench. The lifting up speed is inferred by the machine learning model according to the temperature, the pattern density and the FFU speed.

According to one example embodiment, a semiconductor wet bench is provided. The semiconductor wet bench includes a temperature sensor, a data receiver, a tank, a lifter and a controller. The temperature sensor is configured to sensing a temperature in the semiconductor wet bench. The data receiver is configured to obtain a pattern density of a wafer. The lifter is disposed above the tank. The controller is connected to the temperature sensor and the data receiver. The controller is configured to infer a lifting up speed, by a machine learning model, at least according to the temperature and the pattern density, and configured to control the lifter according to the lifting up speed to pull the wafer out of the tank.

According to one example embodiment, in the semiconductor wet bench described in the previous embodiments, the data receiver is further configured to obtain a wafer information including a material of a top layer and a material of a substrate of the wafer. The lifting up speed is inferred by the machine learning model according to the temperature, the pattern density and the wafer information.

According to one example embodiment, the semiconductor wet bench described in the previous embodiments further includes a vibration sensor. The vibration sensor is connected to the lifter and configured to obtain a lifter vibration. The lifting up speed is inferred by the machine learning model according to the temperature, the pattern density and the lifter vibration.

According to one example embodiment, the semiconductor wet bench described in the previous embodiments further includes a humidity sensor. The humidity sensor is configured to obtain a humidity in the semiconductor wet bench. The lifting up speed is inferred by the machine learning model according to the temperature, the pattern density and the humidity.

According to one example embodiment, in the semiconductor wet bench described in the previous embodiments, the data receiver is further configured to obtain a die number per wafer. The lifting up speed is inferred by the machine learning model according to the temperature, the pattern density and the die number per wafer.

According to one example embodiment, in the semiconductor wet bench described in the previous embodiments, the data receiver is further configured to obtain a wafer number per lot. The lifting up speed is inferred by the machine learning model according to the temperature, the pattern density and the wafer number per lot.

According to one example embodiment, in the semiconductor wet bench described in the previous embodiments, the data receiver is further configured to obtain an exhaust speed in the semiconductor wet bench. The lifting up speed is inferred by the machine learning model according to the temperature, the pattern density and the exhaust speed.

According to one example embodiment, in the semiconductor wet bench described in the previous embodiments, the data receiver is further configured to obtain a fan filter unit (FFU) speed in the semiconductor wet bench. The lifting up speed is inferred by the machine learning model according to the temperature, the pattern density and the FFU speed.

According to one example embodiment, a controller disposed in a semiconductor wet bench is provided. The controller is connected to a temperature sensor and a data receiver, the controller is configured to infer a lifting up speed, by a machine learning model, at least according to a temperature sensed by the temperature sensor and a pattern density of a wafer obtained by the data receiver, and configured to control a lifter according to the lifting up speed to pull the wafer out of a tank.

According to one example embodiment, for the controller described in the previous embodiments, the data receiver is further configured to obtain a wafer information including a material of a top layer and a material of a substrate. The lifting up speed is inferred by the machine learning model according to the temperature, the pattern density and the wafer information including a material of a top layer and a material of a substrate.

According to one example embodiment, for the controller described in the previous embodiments, a vibration sensor is connected to the lifter and configured to obtain a lifter vibration. The lifting up speed is inferred by the machine learning model according to the temperature, the pattern density and the lifter vibration.

According to one example embodiment, for the controller described in the previous embodiments, a humidity sensor is configured to obtain a humidity in the semiconductor wet bench. The lifting up speed is inferred by the machine learning model according to the temperature, the pattern density and the humidity.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A controlling method of a semiconductor wet bench, comprising:
obtaining a temperature in the semiconductor wet bench;
obtaining a pattern density of a wafer;
inferring, by a machine learning model, a lifting up speed at least according to the temperature and the pattern density; and
controlling a lifter according to the lifting up speed.

2. The controlling method according to claim 1, further comprising:
obtaining a wafer information including a material of a top layer and a material of a substrate of the wafer;
wherein the lifting up speed is inferred by the machine learning model according to the temperature, the pattern density and the wafer information.

3. The controlling method according to claim 1, further comprising:
obtaining a lifter vibration;
wherein the lifting up speed is inferred by the machine learning model according to the temperature, the pattern density and the lifter vibration.

4. The controlling method according to claim 1, further comprising:
obtaining a humidity in the semiconductor wet bench;
wherein the lifting up speed is inferred by the machine learning model according to the temperature, the pattern density and the humidity.

5. The controlling method according to claim 1, further comprising:
obtaining a die number per wafer;
wherein the lifting up speed is inferred by the machine learning model according to the temperature, the pattern density and the die number per wafer.

6. The controlling method according to claim 1, further comprising:
obtaining a wafer number per lot;
wherein the lifting up speed is inferred by the machine learning model according to the temperature, the pattern density and the wafer number per lot.

7. The controlling method according to claim 1, further comprising:
obtaining an exhaust speed in the semiconductor wet bench;
wherein the lifting up speed is inferred by the machine learning model according to the temperature, the pattern density and the exhaust speed.

8. The controlling method according to claim 1, further comprising:
obtaining a fan filter unit (FFU) speed in the semiconductor wet bench;
wherein the lifting up speed is inferred by the machine learning model according to the temperature, the pattern density and the FFU speed.

9. A semiconductor wet bench, comprising:
a temperature sensor, configured to sensing a temperature in the semiconductor wet bench;
a data receiver, configured to obtain a pattern density of a wafer;
a tank;
a lifter, disposed above the tank; and
a controller, connected to the temperature sensor and the data receiver, wherein the controller is configured to inferred a lifting up speed, by a machine learning model, at least according to the temperature and the pattern density, and configured to control the lifter according to the lifting up speed to pull the wafer out of the tank.

10. The semiconductor wet bench according to claim 9, wherein
the data receiver is further configured to obtain a wafer information including a material of a top layer and a material of a substrate of the wafer; and
the lifting up speed is inferred by the machine learning model according to the temperature, the pattern density and the wafer information.

11. The semiconductor wet bench according to claim 9, further comprising:
a vibration sensor, connected to the lifter and configured to obtain a lifter vibration;
wherein the lifting up speed is inferred by the machine learning model according to the temperature, the pattern density and the lifter vibration.

12. The semiconductor wet bench according to claim 9, further comprising:
a humidity sensor, configured to obtain a humidity in the semiconductor wet bench;
wherein the lifting up speed is inferred by the machine learning model according to the temperature, the pattern density and the humidity.

13. The semiconductor wet bench according to claim 9, wherein the data receiver is further configured to obtain a die number per wafer;
wherein the lifting up speed is inferred by the machine learning model according to the temperature, the pattern density and the die number per wafer.

14. The semiconductor wet bench according to claim 9, wherein the data receiver is further configured to obtain a wafer number per lot;
wherein the lifting up speed is inferred by the machine learning model according to the temperature, the pattern density and the wafer number per lot.

15. The semiconductor wet bench according to claim 9, wherein the data receiver is further configured to obtain an exhaust speed in the semiconductor wet bench;
wherein the lifting up speed is inferred by the machine learning model according to the temperature, the pattern density and the exhaust speed.

16. The semiconductor wet bench according to claim 9, wherein the data receiver is further configured to obtain a fan filter unit (FFU) speed in the semiconductor wet bench;
wherein the lifting up speed is inferred by the machine learning model according to the temperature, the pattern density and the FFU speed.

17. A controller disposed in a semiconductor wet bench, wherein the controller is connected to a temperature sensor and a data receiver, the controller is configured to infer a lifting up speed, by a machine learning model, at least according to a temperature sensed by the temperature sensor and a pattern density of a wafer obtained by the data receiver, and configured to control a lifter according to the lifting up speed to pull the wafer out of a tank.

18. The controller according to claim 17, wherein
the data receiver is further configured to obtain a wafer information including a material of a top layer and a material of a substrate; and
the lifting up speed is inferred by the machine learning model according to the temperature, the pattern density and the wafer information including a material of a top layer and a material of a substrate.

19. The controller according to claim 17, wherein
a vibration sensor is connected to the lifter and configured to obtain a lifter vibration; and
the lifting up speed is inferred by the machine learning model according to the temperature, the pattern density and the lifter vibration.

20. The controller according to claim 17, wherein a humidity sensor is configured to obtain a humidity in the semiconductor wet bench; and
the lifting up speed is inferred by the machine learning model according to the temperature, the pattern density and the humidity.
